(19) United States
(12) Patent Application Publication
(10) Pub. No.: US 2020/0075313 A1
(43) Pub. Date: Mar. 5, 2020

(54) Oxide Removal From Titanium Nitride Surfaces

(71) Applicant: Mattson Technology, Inc., Fremont, CA (US)

(72) Inventors: Jin J. Wang, Oakland, CA (US); Hua Chung, Saratoga, CA (US)

(21) Appl. No.: 16/534,149

(22) Filed: Aug. 7, 2019

Related U.S. Application Data
(60) Provisional application No. 62/725,337, filed on Aug. 31, 2018.

(51) Int. Cl. H01L 21/02

(52) U.S. Cl. CPC H01L 21/0234; H01L 21/02186

(57) ABSTRACT

Systems and processes for oxide removal from titanium nitride surfaces are provided. In one example implementation, A method includes placing a workpiece on a workpiece support in a processing chamber. The workpiece can have a titanium nitride layer. The method can include performing a plasma-based oxide removal process on the titanium nitride layer. The plasma-based oxide removal process can include: generating one or more species by inducing a plasma in a process gas with a plasma source; and exposing the workpiece to species generated in the plasma. The process gas can include a mixture of a first gas and a second gas. The first gas can include one or more of a hydrogen containing gas and a nitrogen containing gas. The second gas can include a fluorine containing gas.

### PRIORITY CLAIM

The present application claims the benefit of priority of U.S. Provisional Application Ser. No. 62/725,337, titled “Oxide Removal from Titanium Nitride Surfaces,” filed on Aug. 31, 2018, which is incorporated herein by reference.

### FIELD

The present disclosure relates generally to semiconductor processing and more particularly, to oxide removal from a workpiece, such as a semiconductor workpiece.

### BACKGROUND

In semiconductor processing, titanium nitride surfaces can be used as a conductive diffusion barrier layer in the manufacture of integrated circuits. For instance, titanium nitride can be used as a conductive diffusion barrier between a semiconductor material (e.g., Si, SiGe, etc.) and a metal, such as aluminum, copper, or tungsten. As a diffusion layer, the titanium nitride can reduce diffusion of metals and other impurities (which can drastically change device performance) into the semiconductor material. As a conductive layer, the titanium nitride layer can serve as a conductive contact layer between metal and semiconductor layers.

### SUMMARY

Aspects and advantages of embodiments of the present disclosure will be set forth in part in the following description, or may be learned from the description, or may be learned through practice of the embodiments.

One example aspect of the present disclosure is directed to a method for processing a workpiece in a plasma processing apparatus. The method includes placing a workpiece on a workpiece support in a processing chamber. The workpiece can have a titanium nitride layer. The method can include performing a plasma-based oxide removal process on the titanium nitride layer. The plasma-based oxide removal process can include: generating one or more species by inducing a plasma in a process gas with a plasma source; and exposing the workpiece to species generated in the plasma. The process gas can include a mixture of a first gas and a second gas. The first gas can include one or more of a hydrogen containing gas and a nitrogen containing gas. The second gas can include a fluorine containing gas.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example plasma processing apparatus according to example embodiments of the present disclosure;

FIG. 2 depicts a flow diagram of an example method according to example embodiments of the present disclosure;

FIG. 3 depicts a flow diagram of an example method according to example embodiments of the present disclosure;

FIG. 4 depicts example results associated with an example oxide removal process according to example embodiments of the present disclosure;

FIG. 5 depicts example post plasma gas injection according to example embodiments of the present disclosure;

FIG. 6 depicts an example plasma processing apparatus according to example embodiments of the present disclosure; and

FIG. 7 depicts an example plasma processing apparatus according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to methods for processing a workpiece having a titanium nitride layer. In semiconductor processing, titanium nitride layers can be used as a conductive diffusion barrier layer in the manufacture of integrated circuits. For instance, titanium nitride can be used as a conductive diffusion barrier between a semiconductor material (e.g., Si, SiGe, etc.) and a metal, such as aluminum, copper, or tungsten. As a diffusion layer, the titanium nitride can reduce diffusion of metals and other impurities (which can drastically change device performance) into the semiconductor material. As a conductive layer, the titanium nitride layer can serve as a conductive contact layer between metal and semiconductor layers.

Titanium nitride layers can readily oxidize upon exposure to atmosphere or oxygen-containing environments. Oxidation of the titanium nitride layer can lead to an undesirable effect of increasing the film resistivity of the titanium nitride, decreasing its efficacy as a conductive layer and ultimately degrading device (e.g., transistor) performance. Oxidation of titanium nitride layers can vary from sample to sample, depending on storage conditions and environment. This variability can lead to unpredictability in performance and/or manufacture of integrated circuits.

Removing oxygen from the titanium nitride film can lead to more controllable and reproducible, etch, strip, surface cleaning and modification processes. Many etch, strip, surface cleaning, and other modification processes are plasma-based processes that are performed in vacuum and can be affected by oxygen-containing environments. In that regard, it can be beneficial if an oxide removal process for a titanium nitride layer can be performed within the same process chamber as these plasma-based processes. In plasma-based processes, materials such as tungsten, silicon dioxide, silicon nitride, and other materials can be simultaneously exposed as the titanium nitride layer. It can be important that these other materials are not damaged during processing of the workpiece.

Example aspects of the present disclosure are directed to plasma-based processes for selectively removing titanium oxides and oxynitrides from a titanium nitride film on a workpiece while leaving other materials on the workpiece undamaged. Removing the titanium oxides and oxynitrides can lead to a reduction in titanium nitride film resistivity. In some embodiments, the plasma-based processes according to example aspects of the present disclosure can remove titanium oxides and/or oxynitrides in situ before, during and/or after other plasma-based processes (e.g., strip, etch, surface cleaning, surface modification, etc.) within the same processing chamber. With appropriate surface treatment after oxide removal, oxygen, oxides, and oxynitrides on and in the titanium nitride film can remain at reduced levels even after exposure to air.

According to example aspects of the present disclosure, a plasma-based oxide removal process for a titanium nitride film on a workpiece can use a plasma containing hydrogen-, nitrogen-, and fluorine-containing species to remove oxides, oxynitrides, and oxygen in the titanium nitride film. This can result in removal of native oxide (and oxynitrides) and lowered film resistivities. In addition, plasma-based oxide removal processes according to example aspects of the present disclosure can result in oxygen content in the titanium nitride layer remaining reduced even after days of exposure to air. The plasma-based oxide removal process according to example aspects of the present disclosure can be combined with one or more other surface modification processes (e.g., nitridation, sulfuration, etc.) to further inhibit oxidation of the titanium nitride film upon exposure to air.

In some example embodiments, a method can include placing a workpiece on a workpiece support in a processing chamber. The method can include generating a plasma (e.g., a direct plasma and/or a remote plasma) in the plasma chamber from a process gas. The process gas can include a mixture of hydrogen gas (H₂), a nitrogen containing gas (e.g., N₂), and a fluorine (F) containing gas. In some embodiments, the process gas can include a carrier gas, such as an inert gas, such as helium, argon, and/or xenon. The fluorine containing gas can be, for instance, CF₄ and/or NF₃. In some embodiments, NH₃ can be used in addition to or as a substitute for the hydrogen gas and/or the nitrogen gas. The method can include exposing the workpiece, including the titanium nitride layer, to hydrogen-, nitrogen-, and/or fluorine-containing species generated in the plasma.

Example process parameters for one example embodiment of the present disclosure are provided below:
Process Gas:
   H₂ Flow Rate: about 1000 to about 8000 SCCM
   N₂ Flow Rate: about 1000 to about 8000 SCCM
   CF₄ Flow Rate: about 0.1 to about 220 SCCM
   Total Process Gas Flow Rate: about 2000 SCCM to about 15000 SCCM
Process Pressure: about 200 mTorr to about 1500 mTorr
Workpiece Temperature: about 90° C. to about 400° C.

In some embodiments, additional plasma-based surface treatment processes can be implemented after oxide removal. Such plasma-based surface treatment processes can include, but are not limited to, plasma nitridation, surface functionalization, polymer deposition, sulfer passivation. The plasma-based surface treatment processes can be performed on the workpiece in the same processing chamber as the oxide removal process.

In some embodiments, oxide removal can be accomplished using post plasma gas injection. For instance, a plasma can be induced in a process gas in a plasma chamber using a plasma source. The process gas can include, for instance, a hydrogen gas and/or an inert gas, such as helium gas. The plasma chamber can be separated from a processing chamber containing the workpiece. For instance, a separation grid that filters ions and allows the passage of neutral species can be disposed between the plasma chamber and the processing chamber. A fluorine-containing gas can be injected into the neutral species downstream of the plasma chamber (e.g., at and/or below the separation grid). The resulting mixture can be exposed to the workpiece for oxide removal in a titanium nitride layer.

Aspects of the present disclosure are discussed with reference to a “workpiece” “wafer” or semiconductor wafer for purposes of illustration and discussion. Those of ordinary skill in the art, using the disclosures provided herein, will understand that the example aspects of the present disclosure can be used in association with any semiconductor substrate or other suitable workpiece. In addition, the use of the term “about” in conjunction with a numerical value is intended to refer to within ten percent (10%) of the stated numerical value. A “pedestal” refers to any structure that can be used to support a workpiece.

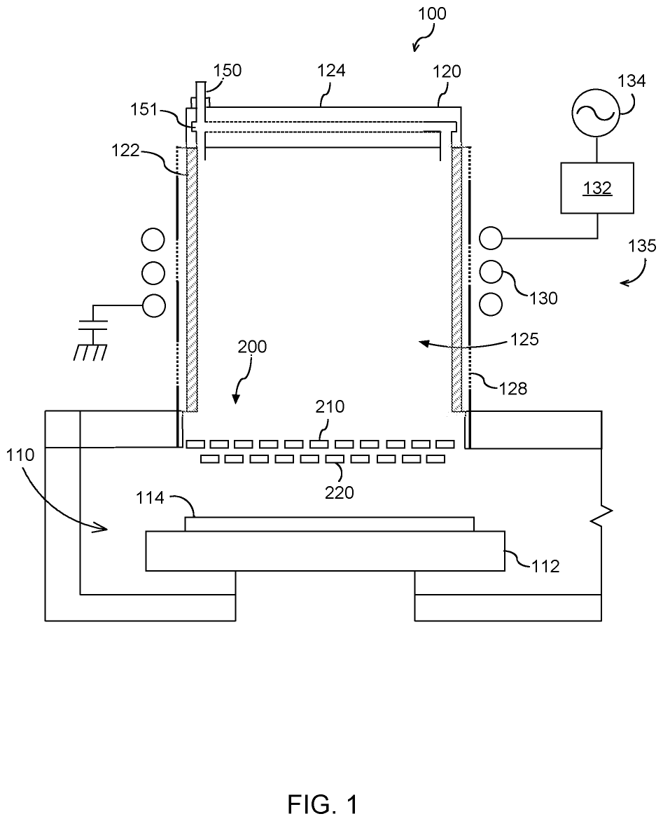

FIG. 1 depicts an example plasma processing apparatus 100 that can be used to perform oxide removal processes according to example embodiments of the present disclosure. FIG. 1 depicts one example processing apparatus that can be used to implement the oxide removal processes according to example aspects of the present disclosure. Those of ordinary skill in the art, using the disclosures provided herein, will understand that other processing apparatus can be used without deviating from the scope of the present disclosure.

As illustrated, plasma processing apparatus 100 includes a processing chamber 110 and a plasma chamber 120 that is separated from the processing chamber 110. Processing chamber 110 includes a workpiece support or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of substrate 114 through a separation grid assembly 200.

Aspects of the present disclosure are discussed with reference to an inductively coupled plasma source for purposes of illustration and discussion. Those of ordinary skill in the art, using the disclosures provided herein, will understand that any plasma source (e.g., inductively coupled plasma source, capacitively coupled plasma source, etc.) can be used without deviating from the scope of the present disclosure.

The plasma chamber 120 includes a dielectric side wall 122 and a ceiling 124. The dielectric side wall 122, ceiling 124, and separation grid 200 define a plasma chamber interior 125. Dielectric side wall 122 can be formed from a dielectric material, such as quartz and/or ceramic (e.g., alumina). The inductively coupled plasma source 135 can include an induction coil 130 disposed adjacent the dielectric side wall 122 about the plasma chamber 120. The induction coil 130 is coupled to an RF power generator 134 through a suitable matching network 132. Process gases (e.g., a hydrogen gas and a carrier gas) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 1, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded. In some embodiments, the grid assembly can include a single grid with one grid plate.

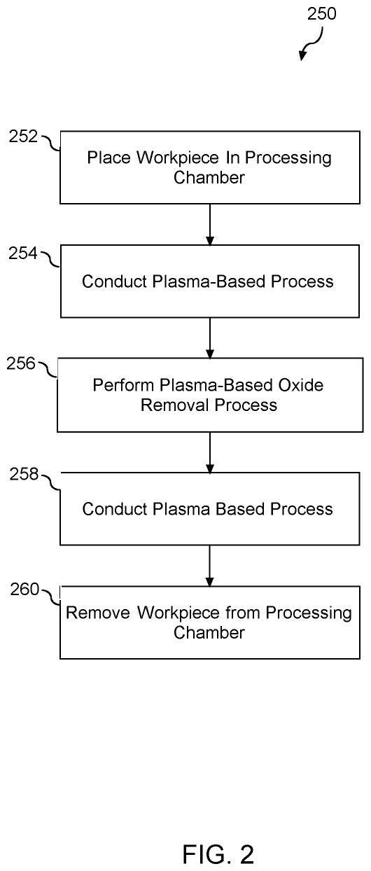

FIG. 2 depicts a flow diagram of one example method (250) according to example aspects of the present disclosure. The method (250) will be discussed with reference to the plasma processing apparatus 100 of FIG. 1 by way of example. The method (250) can be implemented in any suitable plasma processing apparatus. FIG. 2 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (252), the method can include placing a workpiece in a processing chamber of a plasma processing apparatus. For instance, the method can include placing a workpiece 114 onto workpiece support 112 in the processing chamber 110. The workpiece can include a titanium nitride layer. The titanium nitride layer can be, for instance, a diffusion barrier between a semiconductor material and a metal on the workpiece.

At (254), the method can optionally include conducting a plasma-based process using the plasma processing apparatus prior to an oxide removal process. The plasma-based process can expose the workpiece to species generated using a plasma source. Example plasma-based processes include plasma etch, plasma strip, plasma-based surface modification, and other processes.

In the example plasma processing apparatus of FIG. 1, the plasma-based process can include inducing a plasma using inductively coupled plasma source 135 in the plasma chamber from a process gas. The separation grid 200 can be used to perform ion filtering from a mixture to generate a filtered mixture. The filtered mixture can be exposed to the workpiece 114 in the processing chamber to perform a plasma etch process, photoresist strip process, surface modification process, or other process. Other plasma based processes can be implemented without deviating from the scope of the present disclosure.

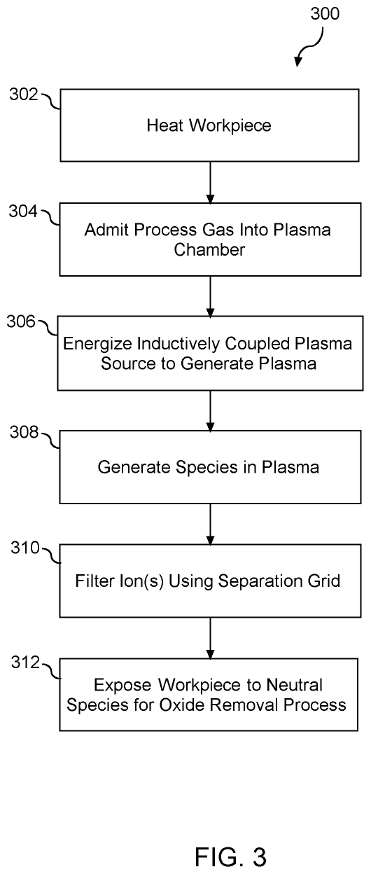

At (256), the method can include performing a plasma-based oxide removal process on the titanium nitride layer on the workpiece. The plasma-based oxide removal process can be any oxide removal process disclosed herein. For instance, the oxide removal process can include one or more of the oxide removal processes discussed with references to FIGS. 3-5. The plasma-based oxide removal process can use a plasma containing hydrogen-, nitrogen-, and fluorine-containing species to remove oxides, oxynitrides, and oxygen in the titanium nitride film.

At (258), the method can optionally include performing a plasma-based process after the oxide removal process. The plasma-based process can expose the workpiece to species generated using a plasma source. Example plasma-based processes include plasma etch, plasma strip, plasma surface treatment, plasma-based surface modification, and other processes.

In the example plasma processing apparatus of FIG. 1, the plasma-based process can include inducing a plasma using inductively coupled plasma source 135 in the plasma chamber from a process gas. The separation grid 200 can be used to perform ion filtering from a mixture to generate a filtered mixture. The filtered mixture can be exposed to the workpiece 114 in the processing chamber to perform an etch process, photoresist strip process, surface modification process, or other process. Other plasma based processes can be implemented without deviating from the scope of the present disclosure.

In some embodiments, the method can include performing a plasma-based surface treatment process to further reduce oxidation of the titanium nitride layer after performing the plasmas-based oxide removal process according to example aspects of the present disclosure. For instance, the plasma-based surface treatment process can include, but it not limited to, plasma nitridation, surface functionalization, polymer deposition, sulfur passivation. The plasma-based surface treatment processes can be performed on the workpiece in the same processing chamber as the oxide removal process.

In some embodiments, the method can include exposing the titanium nitride layer to organic radicals (e.g., methyl radicals) in the processing chamber. The organic radicals can be generated, for instance, by dissociating a hydrocarbon gas using a plasma and/or by mixing a hydrocarbon gas (e.g. CH₄) with species (e.g., excited H radicals, excited inert gas molecules, etc.) using post plasma gas injection. The methyl radicals can reduce the formation of oxides in the titanium nitride layer.

At (210), the method can include removing the workpiece from the processing chamber. For instance, the workpiece 114 can be removed from workpiece support 112 in the processing chamber 110. The plasma processing apparatus can then be conditioned for future processing of additional workpieces. In this way, both the oxide removal process (206) and one or more optional plasma-based processes (204), (208) can be performed using the same processing apparatus while the workpiece is in the same processing chamber without having to remove the workpiece. This can reduce processing latencies resulting from moving the workpiece among different processing chambers and exposing the workpiece to atmosphere.

FIG. 3 depicts a flow diagram of an example oxide removal process (300) according to example aspects of the present disclosure. The process (300) can be implemented using the plasma processing apparatus 100. However, as will be discussed in detail below, the methods according to example aspects of the present disclosure can be implemented using other approaches without deviating from the scope of the present disclosure. FIG. 3 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various additional steps (not illustrated) can be performed without deviating from the scope of the present disclosure.

At (302), the oxide removal process can include heating the workpiece. For instance, the workpiece 114 can be heated in the process chamber to a process temperature. The workpiece 114 can be heated, for instance, using one or more heating systems associated with the pedestal 112. In some embodiments, the workpiece can be heated to a process temperature in the range of about 90° C. to about 400° C.

At (304), the oxide removal process can include admitting a process gas into the plasma chamber. For instance, a process gas can be admitted into the plasma chamber interior 125 from a gas source 150 via annular gas distribution channel 151 or other suitable gas introduction mechanism.

In some embodiments, the process gas can be a mixture of a first gas and a second gas. In some embodiments, the first gas can be a mixture of a hydrogen containing gas and a nitrogen containing gas. For instance, in some embodiments, the first gas can be a mixture of H₂ and N₂. In some embodiments, the first gas can be NH₃. In some embodiments, the first gas can be a mixture of H₂, N₂ and NH₃.

In some embodiments, the second gas can be a fluorine containing gas. For instance, the second gas can be CF₄. In some embodiments, the second gas can be NF₃.

In some embodiments, the process gas comprises an H₂ gas, an N₂ gas, and a CF₄ gas, a flow rate of the H₂ gas being in the range of about 1000 standard cubic centimeters per minute (SCCM) to about 8000 SCCM, a flow rate of N₂ gas being in the range of about 1000 SCCM to about 8000 SCCM, a flow rate of the CF₄ gas being in the range of about 0.1 SCCM to about 220 SCCM. A total flow rate of the process gas can be in the range of about 2000 SCCM to about 15000 SCCM.

At (306), the oxide removal process can include energizing an inductively coupled plasma source to generate a plasma in a plasma chamber. For instance, induction coil 130 can be energized with RF energy from RF power generator 134 to generate a plasma in the plasma chamber interior 125. In some embodiments, the inductively coupled plasma source can be energized with pulsed power to obtain desired radicals with reduced plasma energy. The plasma can be used to generate one or more species at (308).

At (310), the oxide removal process can include filtering one or more ions generated by the plasma to create a filtered mixture. The filtered mixture can include neutral radicals. In some embodiments, the one or more ions can be filtered using a separation grid assembly separating the plasma chamber from a processing chamber where the workpiece is located. For instance, separation grid assembly 200 can be used to filter ions generated by the plasma. The separation grid 200 can have a plurality of holes. Charged particles (e.g., ions) can recombine on the walls in their path through the plurality of holes. Neutral species (e.g. radicals) can pass through the holes.

In some embodiments, the separation grid 200 can be configured to filter ions with an efficiency greater than or equal to about 90%, such as greater than or equal to about 95%. A percentage efficiency for ion filtering refers to the amount of ions removed from the mixture relative to the total number of ions in the mixture. For instance, an efficiency of about 90% indicates that about 90% of the ions are removed during filtering. An efficiency of about 95% indicates that about 95% of the ions are removed during filtering.

In some embodiments, the separation grid can be a multi-plate separation grid. The multi-plate separation grid can have multiple separation grid plates in parallel. The arrangement and alignment of holes in the grid plate can be selected to provide a desired efficiency for ion filtering, such as greater than or equal to about 95%.

For instance, the separation grid 200 can have a first grid plate 210 and a second grid plate 220 in parallel relationship with one another. The first grid plate 210 can have a first grid pattern having a plurality of holes. The second grid plate 220 can have a second grid pattern having a plurality of holes. The first grid pattern can be the same as or different from the second grid pattern. Charged particles (e.g., ions) can recombine on the walls in their path through the holes of each grid plate 210, 220 in the separation grid 200. Neutral species (e.g., radicals) can flow relatively freely through the holes in the first grid plate 210 and the second grid plate 220.

At (312) of FIG. 3, the oxide removal process can include exposing the workpiece to the species. More particularly, the workpiece can be exposed to species generated in the plasma and passing through the separation grid assembly. As an example, hydrogen-, nitrogen-, and fluorine-containing species can pass through the separation grid 200 and be exposed to the workpiece 114. Exposing the workpiece to fluorine-containing species can result in removal of oxides, oxynitrides, and oxygen from the titanium nitride layer.

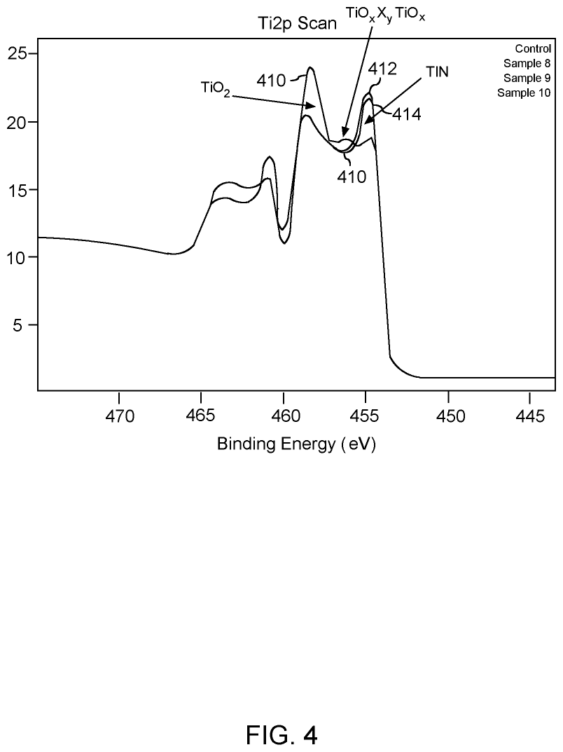

FIG. 4 depicts example results associated with an example oxide removal process according to example embodiments of the present disclosure. More particularly, FIG. 4 depicts x-ray photoelectron spectroscopy (XPS) spectra of the titanium 2p peak showing changes in chemical bonding of titanium in titanium nitride layers before and after an oxide removal process. Curve 410 is associated with a “control” sample associates with the as-deposited sample of titanium nitride. Curves 412 and 414 are associated with two samples “9” and “10.” Samples 9 and 10 were treated using an oxide removal process with a plasma induced in an H₂/N₂/CF₄ process gas for 1 minute. Curve 416 is associated with a sample “8”. Sample 8 was treated using an oxide removal process with a plasma induced in an Ar/H₂/CF₄ process gas for 1 minute. All samples were exposed to air before and after the oxide removal process. Curves 410, 412, 414, and 416 demonstrate that TiO₂ and TiON were removed after the plasma oxide removal process.

Table 1 below provides the elemental composition of the samples as measured from XPS. Table 1 demonstrates that the oxygen content was reduced after performing a plasma-based oxide removal process according to example aspects of the present disclosure.

TABLE 1

| Sample ID | C 1s % | F 1s % | N 1s % | O 1s % | Si 2p % | Ti 2p % |
|---|---|---|---|---|---|---|
| Control | 8.4 | 1.2 | 30.6 | 26.7 | 1.2 | 31.9 |
| 10 | 6.1 | 2.2 | 32.6 | 24.0 | 1.8 | 33.4 |
| 9 | 6.2 | 2.9 | 34.2 | 21.5 | 1.3 | 34.0 |
| 8 | 6.2 | 2.5 | 34.9 | 21.1 | 1.8 | 33.6 |

Table 2 below provides data associated with sheet resistances of Sample 10 before and after the oxide removal process. As shown the resistance of the titanium nitride layer was reduced.

TABLE 2

| Sample ID | Before | After | Change in R | % Change in R |
|---|---|---|---|---|
| 10 | 22.458 | 16.994 | 5.464 | 24.3 |

In some embodiments, the oxide removal process from a titanium nitride layer on a workpiece can be implemented using post-plasma gas injection. Post plasma gas injection can involve mixing a fluorine-containing gas into neutral species downstream of a plasma. In some embodiments, the fluorine-containing gas can be mixed with neutral species at or below a separation grid that separates a processing chamber containing the workpiece and a plasma chamber where the plasma is induced in a process gas. Post-plasma gas injection according to example embodiments of the present disclosure can result in generation of fluorine containing radicals for exposure to a workpiece. The fluorine containing radicals can be used for oxide removal of a titanium nitride layer on the workpiece.

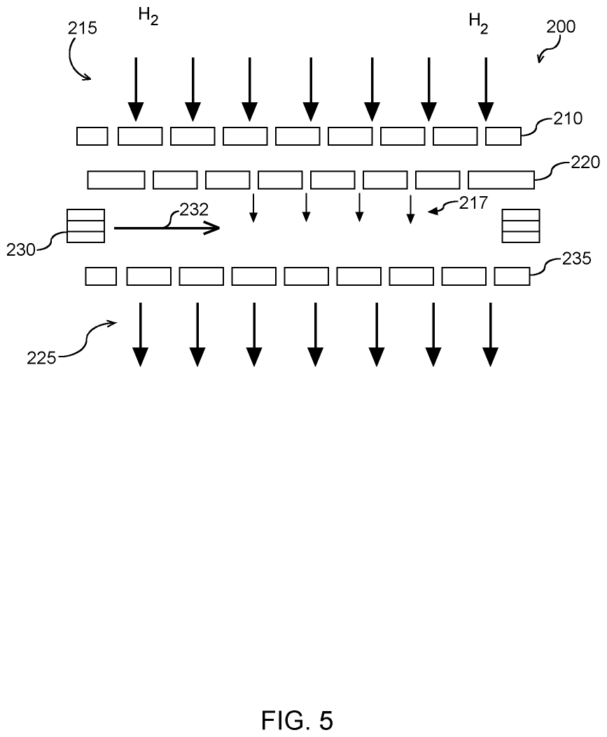

FIG. 5 depicts example generation of fluorine-containing radicals using post-plasma gas injection according to example embodiments of the present disclosure. More particularly, FIG. 5 depicts an example separation grid 200 for injection of a fluorine containing gas post-plasma according to example embodiments of the present disclosure. The separation grid 200 includes a first grid plate 210 and a second grid plate 220 disposed in parallel relationship. The first grid plate 210 and the second grid plate 220 can provide for ion/UV filtering.

The first grid plate 210 and a second grid plate 220 can be in parallel relationship with one another. The first grid plate 210 can have a first grid pattern having a plurality of holes. The second grid plate 220 can have a second grid pattern having a plurality of holes. The first grid pattern can be the same as or different from the second grid pattern. Species 215 from the plasma can be exposed to the separation grid 200. Charged particles (e.g., ions) can recombine on the walls in their path through the holes of each grid plate 210, 220 in the separation grid 200. Neutral species can flow relatively freely through the holes in the first grid plate 210 and the second grid plate 220.

Subsequent to the second grid plate 220, a gas injection source 230 can be configured to mix a fluorine-containing gas 232 into the species 237 passing through the separation grid 200. In some embodiments, the fluorine-containing gas is CF₄. In some embodiments, the fluorine-containing gas is NF₄. A mixture 225 including fluorine-containing radicals resulting from the injection of the fluorine-containing gas can pass through a third grid plate 235 for exposure to the workpiece in the processing chamber.

The present example is discussed with reference to a separation grid with three grid plates for example purposes. Those of ordinary skill in the art, using the disclosures provided herein, will understand that more or fewer grid plates can be used without deviating from the scope of the present disclosure. In addition, the fluorine-containing gas can be mixed with the species at any point in the separation grid and/or after the separation grid in the processing chamber. For instance, the gas injection source 230 can be located between first grid plate 210 and second grid plate 220.

The oxide removal process and/or plasma strip process can be implemented using other plasma processing apparatus without deviating from the scope of the present disclosure.

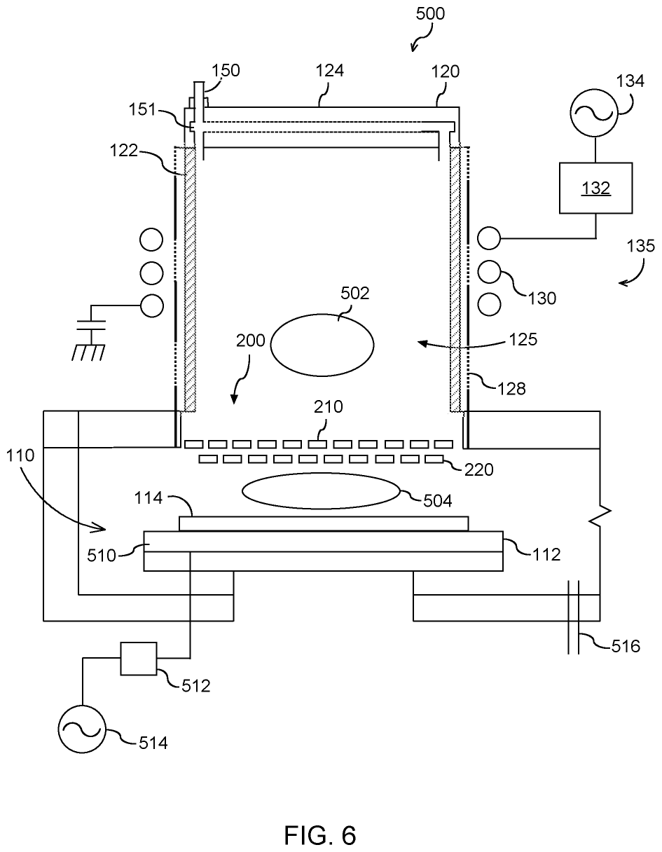

FIG. 6 depicts an example plasma processing apparatus 500 that can be used to implement processes according to example embodiments of the present disclosure. The plasma processing apparatus 500 is similar to the plasma processing apparatus 100 of FIG. 1.

More particularly, plasma processing apparatus 500 includes a processing chamber 110 and a plasma chamber 120 that is separated from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of substrate 114 through a separation grid assembly 200.

The plasma chamber 120 includes a dielectric side wall 122 and a ceiling 124. The dielectric side wall 122, ceiling 124, and separation grid 200 define a plasma chamber interior 125. Dielectric side wall 122 can be formed from a dielectric material, such as quartz and/or alumina. The inductively coupled plasma source 135 can include an induction coil 130 disposed adjacent the dielectric side wall 122 about the plasma chamber 120. The induction coil 130 is coupled to an RF power generator 134 through a suitable matching network 132. Process gases (e.g., an inert gas) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 6, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

The example plasma processing apparatus 500 of FIG. 6 is operable to generate a first plasma 502 (e.g., a remote plasma) in the plasma chamber 120 and a second plasma 504 (e.g., a direct plasma) in the processing chamber 110. As used herein, a “remote plasma” refers to a plasma generated remotely from a workpiece, such as in a plasma chamber separated from a workpiece by a separation grid. As used herein, a “direct plasma” refers to a plasma that is directly exposed to a workpiece, such as a plasma generated in a processing chamber having a pedestal operable to support the workpiece.

More particularly, the plasma processing apparatus 500 of FIG. 6 includes a bias source having bias electrode 510 in the pedestal 112. The bias electrode 510 can be coupled to an RF power generator 514 via a suitable matching network 512. When the bias electrode 510 is energized with RF energy, a second plasma 504 can be generated from a mixture in the processing chamber 110 for direct exposure to the workpiece 114. The processing chamber 110 can include a gas exhaust port 516 for evacuating a gas from the processing chamber 110. The species used in the oxide removal processes according to example aspects of the present disclosure can be generated using the first plasma 502 and/or the second plasma 504.

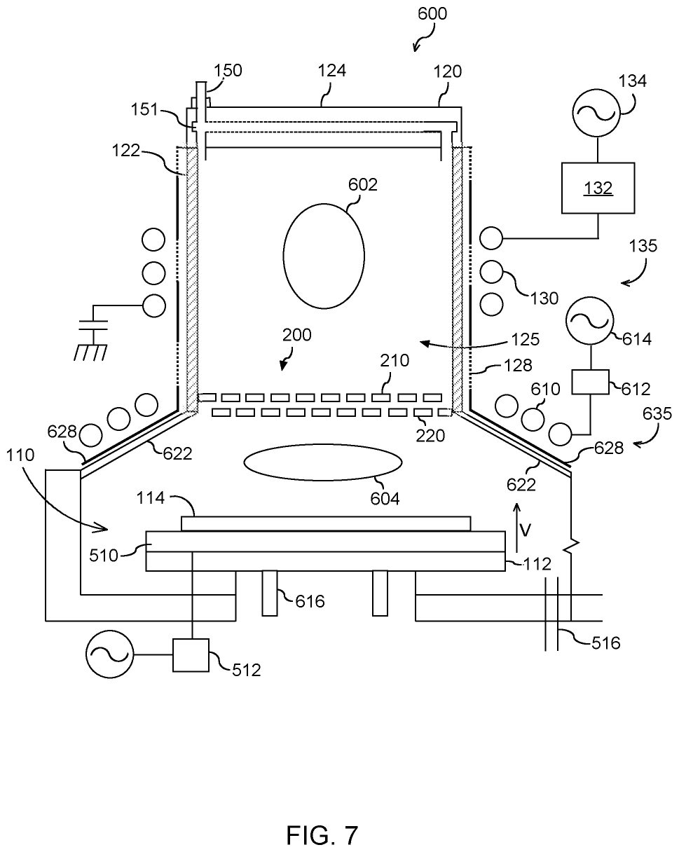

FIG. 7 depicts a processing chamber 600 similar to that of FIG. 2 and FIG. 7. More particularly, plasma processing apparatus 600 includes a processing chamber 110 and a plasma chamber 120 that is separated from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of substrate 114 through a separation grid assembly 200.

The plasma chamber 120 includes a dielectric side wall 122 and a ceiling 124. The dielectric side wall 122, ceiling 124, and separation grid 200 define a plasma chamber interior 125. Dielectric side wall 122 can be formed from a dielectric material, such as quartz and/or alumina. The inductively coupled plasma source 135 can include an induction coil 130 disposed adjacent the dielectric side wall 122 about the plasma chamber 120. The induction coil 130 is coupled to an RF power generator 134 through a suitable matching network 132. Process gas (e.g., an inert gas) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 7, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

The example plasma processing apparatus 600 of FIG. 7 is operable to generate a first plasma 602 (e.g., a remote plasma) in the plasma chamber 120 and a second plasma 604 (e.g., a direct plasma) in the processing chamber 110. As shown, the plasma processing apparatus 600 can include an angled dielectric sidewall 622 that extends from the vertical sidewall 122 associated with the remote plasma chamber 120. The angled dielectric sidewall 622 can form a part of the processing chamber 110.

A second inductive plasma source 635 can be located proximate the dielectric sidewall 622. The second inductive plasma source 635 can include an induction coil 610 coupled to an RF generator 614 via a suitable matching network 612. The induction coil 610, when energized with RF energy, can induce a direct plasma 604 from a mixture in the processing chamber 110. A Faraday shield 628 can be disposed between the induction coil 610 and the sidewall 622.

The pedestal 112 can be movable in a vertical direction V. For instance, the pedestal 112 can include a vertical lift 616 that can be configured to adjust a distance between the pedestal 112 and the separation grid assembly 200. As one example, the pedestal 112 can be located in a first vertical position for processing using the remote plasma 602. The pedestal 112 can be in a second vertical position for processing using the direct plasma 604. The first vertical position can be closer to the separation grid assembly 200 relative to the second vertical position.

The plasma processing apparatus 600 of FIG. 7 includes a bias source having bias electrode 510 in the pedestal 112. The bias electrode 510 can be coupled to an RF power generator 514 via a suitable matching network 512. The processing chamber 110 can include a gas exhaust port 516 for evacuating a gas from the processing chamber 110. The species used in the oxide removal processes according to example aspects of the present disclosure can be generated using the first plasma 602 and/or the second plasma 604.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method for processing a workpiece in a plasma processing apparatus, the method comprising:
placing a workpiece on a workpiece support in a processing chamber, the workpiece having a titanium nitride layer;
performing a plasma-based oxide removal process on the titanium nitride layer, the plasma-based oxide removal process comprising:
generating one or more species by inducing a plasma in a process gas with a plasma source;
exposing the workpiece to species generated in the plasma;
wherein the process gas comprises a mixture of a first gas and a second gas, the first gas comprising one or more of a hydrogen containing gas and a nitrogen containing gas, the second gas comprising a fluorine containing gas.

2. The method of claim 1, wherein the first gas comprises an H₂ gas and an N₂ gas.

3. The method of claim 1, wherein the first gas comprises a NH₃ gas.

4. The method of claim 1, wherein the first gas comprises an H₂ gas, an N₂ gas, and an NH₃ gas.

5. The method of claim 1, wherein the second gas comprises CF₄ gas.

6. The method of claim 1, wherein the second gas comprises NF₃ gas.

7. The method of claim 1, wherein the process gas comprises an H₂ gas, an N₂ gas, and a CF₄ gas, a flow rate of the H₂ gas being in a range of about 1000 SCCM to about 8000 SCCM, a flow rate of N₂ gas being in a range of about 1000 SCCM to about 8000 SCCM, a flow rate of the CF₄ gas being in a range of about 0.1 SCCM to about 220 SCCM.

8. The method of claim 7, wherein a total flow rate of the process gas is in a range of about 2000 SCCM to about 15000 SCCM.

9. The method of claim 1, wherein during the plasma-based oxide removal process, a pressure in the processing chamber is in a range of about 200 mTorr to about 1500 mTorr.

10. The method of claim 1, wherein during the plasma-based oxide removal process, a temperature of the workpiece is in a range of about 90° C. to about 400° C.

11. The method of claim 1, wherein the plasma source comprises an inductively coupled plasma source.

12. The method of claim 1, wherein the plasma is generated in a plasma chamber that is separated from the processing chamber by a separation grid.

13. The method of claim 1, wherein the method comprises performing a plasma-based process on the workpiece in the processing chamber without removing the workpiece.

14. The method of claim 12, wherein the plasma-based process comprises one or more of a plasma etch process, a plasma strip process, or a plasma surface treatment process.

15. A method for processing a workpiece, comprising:
placing the workpiece on a workpiece support in a processing chamber, the workpiece comprising a titanium nitride layer;
generating one or more species by inducing a plasma in a process gas in a plasma chamber;
filtering one or more ions from the one or more species using a separation grid separating the plasma chamber from a processing chamber;
injecting a fluorine containing gas downstream of the plasma chamber into the one or more species to generate a second mixture;
exposing the workpiece to the second mixture in the processing chamber to remove oxide from the titanium nitride layer.

16. The method of claim 15, wherein the fluorine containing gas comprises NF₃.

17. The method of claim 15, wherein the fluorine containing gas comprises CF₄.

18. The method of claim 15, wherein the process gas comprises hydrogen.

19. A method for processing, the method comprising:
placing a workpiece on a workpiece support in a processing chamber, the workpiece having a titanium nitride layer;
performing a plasma-based oxide removal process on the titanium nitride layer using a first plasma generated using a first process gas in a plasma chamber, the plasma-based oxide removal process comprising:
generating one or more species in a plasma chamber by inducing a plasma in a process gas with a plasma source;
filtering ions generated using the plasma with a separation grid separating the plasma chamber from the processing chamber; and
exposing the workpiece to neutral species generated in the plasma in the processing chamber;
performing a plasma-based process on the workpiece using a second plasma generated using a second process gas in the plasma chamber;
removing the workpiece from the processing chamber;
wherein the first process gas comprises an H₂ gas, an N₂ gas, and a fluorine containing gas, a flow rate of the H₂ gas being in a range of about 1000 SCCM to about 8000 SCCM, a flow rate of N₂ gas being in a range of about 1000 SCCM to about 8000 SCCM, a flow rate of the CF₄ gas being in a range of about 0.1 SCCM to about 220 SCCM.

20. The method of claim 17, wherein the second process gas is different from the first process gas.
